(19) United States
(12) Patent Application Publication
(10) Pub. No.: US 2021/0392758 A1
(43) Pub. Date: Dec. 16, 2021

(54) THIN CIRCUIT BOARD AND METHOD OF MANUFACTURING THE SAME

(71) Applicants: Avary Holding (Shenzhen) Co., Limited., Shenzhen (CN); QING DING PRECISION ELECTRONICS (HUAIAN) CO.,LTD, Huai an (CN)

(72) Inventors: HSIAO-TING HSU, New Taipei (TW); MING-JAAN HO, New Taipei (TW); FU-YUN SHEN, Shenzhen (CN); XIAN-QIN HU, Shenzhen (CN)

(21) Appl. No.: 17/419,412

(22) PCT Filed: Oct. 31, 2019
(86) PCT No.: PCT/CN2019/114604

§ 371 Date: Jun. 29, 2021

(51) Int. Cl. H05K 3/46; H05K 1/03

(52) U.S. Cl. CPC H05K 3/4688; H05K 1/036; H05K 2201/0141; H05K 2203/0278; H05K 2201/0195; H05K 2201/0154; H05K 2201/0191

(57) ABSTRACT

A thin circuit board (100) and a method of manufacturing the same, the thin circuit board (100) includes: a dielectric layer (40); an inner circuit substrate (30); and a metal layer (50) formed on at least one side of the inner circuit substrate (30). The metal layer (450) is covered by the dielectric layer (40). The dielectric layer (40) includes an outermost insulating layer (11) and a bonding structure (20) sandwiched between the inner circuit substrate (30) and the metal layer (50), the metal layer (50) is wrapped by the insulating layer (11) and the bonding structure (20).

### FIELD

The subject matter herein generally relates to a field of circuit board, especially to a thin circuit board and a method of manufacturing the same.

### BACKGROUND

In recent years, electronic products have been widely used in daily work and life, and light, thin, and small electronic products have become more and more popular. As a main component of the electronic product, the flexible circuit board occupies a large space of the electronic product. Therefore, the volume of the flexible circuit board affects the volume of the electronic product to a large extent. Large-volume flexible circuit boards are difficult to meet the trend of light, thin, short, and small electronic products.

### SUMMARY

What is needed, is a method of manufacturing a thin circuit board with a reduced thickness.

What is also needed, is a thin circuit board.

A method of manufacturing a thin circuit board includes the following steps:

providing a laminated board, the laminated board comprising an insulating layer and a metal layer formed on a side of the insulating layer;

providing a bonding structure, the bonding structure comprising an insulating substrate and a conductive pillar penetrating two opposite surfaces of the insulating substrate;

arranging the bonding structure between the laminated board and an inner circuit substrate, a side of the metal layer facing away from the insulating layer facing the inner circuit substrate;

pressing the laminated board, the bonding structure, and the inner circuit substrate to form the thin circuit board, wherein the pillar electrically connects the metal layer and the inner circuit substrate.

Further, the insulating substrate comprises a first base, a second base, and a third base stacked in that sequence, wherein a mechanical strength of the second base is greater than a mechanical strength of the first base, and is greater than a mechanical strength of the third base.

Further, the first base and the third base are both insulating films made of a mixture of teflon and liquid crystal polymer or a mixture of teflon and polyimide, the second base is a polyimide film.

Further, in the mixture, a weight percentage of the liquid crystal polymer or the polyimide is 1% to 10%.

Further, a thickness of the first base and a thickness of the third base are 12.5 μm to 50 μm, respectively; a thickness of the second base is 7 μm to 50 μm.

Further, the metal layer is a wiring layer or a metal foil.

Further, the inner circuit substrate comprises a signal line, an opening is formed on the metal layer corresponding to the signal line.

A thin circuit board includes:

a dielectric layer;

an inner circuit substrate; and

a metal layer formed on at least one side of the inner circuit substrate;

the metal layer is covered by the dielectric layer, the dielectric layer comprises an outermost insulating layer and a bonding structure sandwiched between the inner circuit substrate and the metal layer, the metal layer is wrapped by the insulating layer and the bonding structure.

Further, the insulating substrate comprises a first base, a second base, and a third base stacked in that sequence, wherein a mechanical strength of the second base is greater than a mechanical strength of the first base, and is greater than a mechanical strength of the third base.

Further, the first base and the third base are both insulating films made of a mixture of teflon and liquid crystal polymer or a mixture of teflon and polyimide, the second base is a polyimide film.

Further, in the mixture, a weight percentage of the liquid crystal polymer or polyimide is 1% to 10%.

Further, the metal layer is a wiring layer or a metal foil.

Further, the inner circuit substrate comprises a signal line, an opening is formed on the metal layer corresponding to the signal line.

The present disclosure of the method of manufacturing the thin circuit board, during pressing, compared to a side of the insulating layer facing away from the outer wiring layer facing to the inner circuit substrate, the s side of the outer wiring layer facing away from the insulating layer facing the inner circuit substrate reduces the thickness of the circuit board after pressing. In addition, the insulating layer may also serve as a covering film for the tin circuit board to protect the tin circuit board, so that the tin circuit board does not need to be provided with a covering film, thereby further reducing the thickness of the tin circuit board.

### BRIEF DESCRIPTION OF THE DRAWINGS

FIG. 1 is a schematic cross-sectional diagram of a single-sided board of an embodiment of the present disclosure.

FIG. 2 is a schematic cross-sectional diagram of a laminated board of an embodiment of the present disclosure.

FIG. 3 is a schematic cross-sectional diagram of a bonding structure of an embodiment of the present disclosure.

FIG. 4 is a schematic cross-sectional diagram of a bonding structure of another embodiment of the present disclosure.

FIG. 5 is a schematic cross-sectional diagram of an inner circuit substrate of an embodiment of the present disclosure.

FIG. 6 is a schematic cross-sectional diagram of a tin circuit board of an embodiment of the present disclosure.

FIG. 7 is a schematic cross-sectional diagram of a tin circuit board of another embodiment of the present disclosure.

FIG. 8 is a schematic cross-sectional diagram of a tin circuit board of another embodiment of the present disclosure.

FIG. 9 is a schematic cross-sectional diagram of a tin circuit board of another embodiment of the present disclosure.

Description of symbols for main elements: 100, 100a, and 100b respectively represent tin circuit boards, 10 represents a single-sided board, 11 represents an insulating layer, 13 represents a metal foil, 130 represents an outer wiring layer, 10a represents a laminated board, 131 represents a connecting pad, 20 represents a bonding structure, 21 represents an insulating substrate, 23 represents a conductive pillar, 211 represents a first base, 213 represents a second base, 215 represents a third base, 210 represents a through hole, 30 represents an inner circuit substrate, 31 represents a signal line, 133 and 110 respectively represent openings, 40 represents a dielectric layer, 50 represents a metal layer.

Implementations of the disclosure will now be described, with reference to the drawings.

### DETAILED DESCRIPTION

Implementations of the disclosure will now be described clearly and completely, by way of embodiments only, with reference to the drawings. Obviously, the described embodiments are only a part of the embodiments of the present disclosure, but not all of the embodiments. The disclosure is illustrative only, and changes may be made in the detail within the principles of the present disclosure. It will, therefore, be appreciated that the embodiments may be modified within the scope of the claims.

Unless otherwise defined, all technical terms used herein have the same meaning as commonly understood by one of ordinary skill in the art. The technical terms used herein are not to be considered as limiting the scope of the embodiments.

Implementations of the disclosure will now be described, by way of embodiments only, with reference to the drawings. It should be noted that non-conflicting details and features in the embodiments of the present disclosure may be combined with each other.

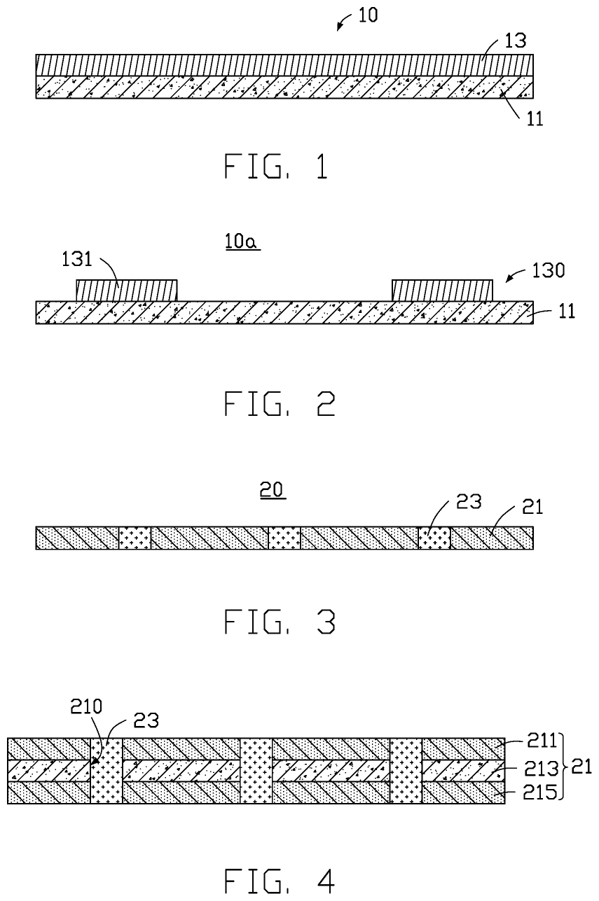

Referring to FIG. 1 to FIG. 9, an embodiment of the present disclosure of a method of manufacturing a thin circuit board includes the following steps:

Step S1, referring to FIG. 1, at least one single-sided board 10 is provided, each single-sided board 10 includes an insulating layer 11 and a metal foil 13 formed on a side of the insulating layer 11.

A material of the insulating layer 11 may be selected from but not limited to at least one of polypropylene, teflon, epoxy resin, polyurethane, phenolic resin, urea-formaldehyde resin, melamine-formaldehyde resin, liquid crystal polymer, polyimide, polyether-ether-ketone, polyethylene glycol terephthalate, and polyethylene naphthalate, etc. In this embodiment, the material of the insulating layer 11 is preferably polyimide.

Preferably, a thickness of the insulating layer 11 is 12 μm to 75 μm, and a thickness of the metal foil 13 is 9 μm to 70 μm. In another embodiment, the thickness of the insulating layer 11 and the thickness of the metal foil 13 may be adjusted as needed.

In this embodiment, the number of the single-sided board 10 is two.

Step S2, referring to FIG. 2, an outer wiring layer 130 is formed by performing a circuit fabrication process on the metal foil 13, thereby correspondingly forming a single-sided circuit substrate as a laminated board 10a by each single-sided board 10.

In some embodiments, the outer wiring layer 130 may include at least one connecting pad 131. Specifically, in this embodiment, each outer wiring layer 130 includes two spaced connecting pads 131.

In some embodiments, the laminated board 10a may be made by directly pressing an outer wiring layer 130 to an insulating layer 11.

Step S3, referring to FIG. 3 and FIG. 4, a bonding structure 20 is provided, the bonding structure 20 includes an insulating substrate 21 and a conductive pillar 23 penetrating two opposite surfaces of the insulating substrate 21.

The insulating substrate 21 may be composed of a single-layer insulating layer or formed by stacking multiple insulating layers.

Preferably, in this embodiment, referring to FIG. 4, the insulating substrate 21 includes a first base 211, a second base 213, and a third base 215 stacked in that sequence. Wherein, a mechanical strength of the second base 213 is greater than a mechanical strength of the first base 211, and is greater than a mechanical strength of the third base 215.

In some embodiments, the first base 211 and the third base 215 are both insulating films made of a mixture of teflon and liquid crystal polymer or a mixture of teflon and polyimide. In the mixture, a weight percentage of the liquid crystal polymer or the polyimide is 1% to 10%. A material of the first base 211 and a material of the third base 215 may be the same or different. The second base 213 may be a polyimide film.

In some embodiments, a thickness of the first base 211 and a thickness of the third base 215 may be 12.5 μm to 50 μm, respectively. In some embodiments, a dielectric constant Dₖ of the first base 211 and the third base 215 are 2.2 to 2.8, dielectric losses D_{f} are 0.001 to 0.003.

A thickness of the second base 213 is 7 μm to 50 μm. Preferably, the thickness of the second base 213 is 12.5 μm to 25 μm.

At least one through hole 210 penetrating two opposite surfaces of the insulating substrate 21 is formed on the insulating substrate 21. Specifically, in this embodiment, the through hole 210 sequentially penetrates the first base 211, the second base 213, and the third base 215. An aperture of the through hole 210 may be 75 μm to 200 μm. Preferably, the aperture of the through hole 210 is 100 μm to 150 μm. A ratio of a depth of the through hole 210 to the aperture is less than 3.

The pillar 23 fills the through hole 210. In this embodiment, the pillar 23 is formed by filling a hole with a conductive paste. In this embodiment, the conductive paste includes at least two of metals such as copper, tin, silver, nickel, aluminum, and molybdenum, etc. Wherein, a weight percentage of metals in the conductive paste is greater than 70%.

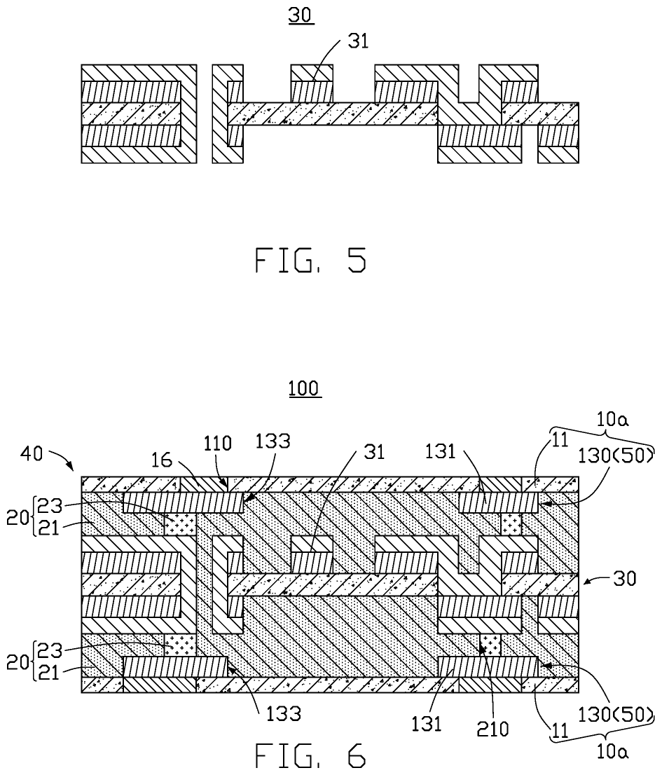

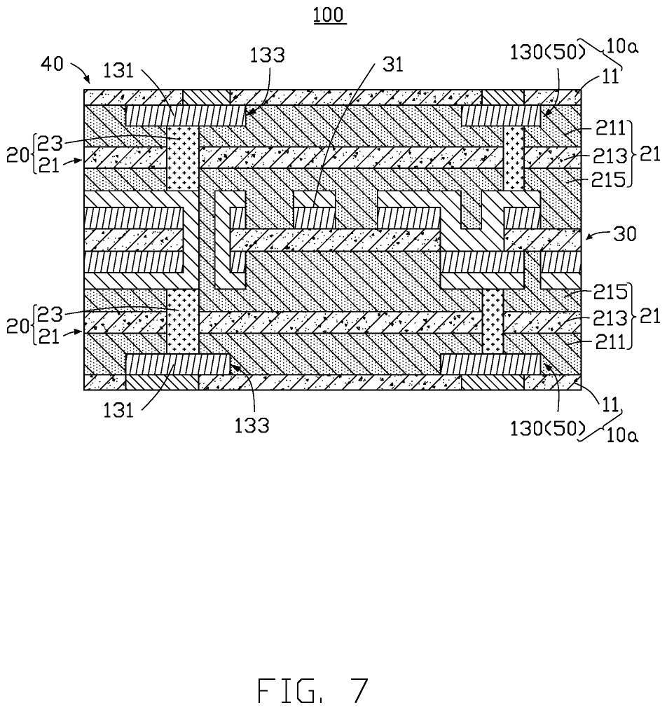

Step S4, referring to FIG. 5, FIG. 6, and FIG. 7, an inner circuit substrate 30 is provided, and the bonding structure 20 is disposed between the laminated board 10a and the inner circuit substrate 30. A side of the outer wiring layer 130 facing away from the insulating layer 11 faces the inner circuit substrate 30. The laminated board 10a, the bonding structure 20, and the inner circuit substrate 30 are pressed to obtaining the thin circuit board 100. Wherein, the pillar 23 electrically connects the inner circuit substrate 30 and the laminated board 10a.

Specifically, in this embodiment, one laminated board 10a, one bonding structure 20, one inner circuit substrate 30, another laminated board 10a, another bonding structure 20, and another inner circuit substrate 30 are stacked in that sequence and pressed to obtain the thin circuit board 100. The side of the outer wiring layer 130 of each laminated board 10a facing away from the insulating layer 11 faces the inner circuit substrate 30 before pressing.

The inner circuit substrate 30 includes at least one signal line 31. In some embodiments, an opening 133 is formed on an area of the outer wiring layer 130 corresponding to the signal line 31, so as to achieve lower loss signal transmission without increasing the thickness of the thin circuit board 100.

Preferably, a pressing temperature during pressing is 200 degree Celsius, a pressing pressure is 42 Kg/qcm, so that there is no microbubbles after pressing, and a flow effect of the bonding structure 20 and the insulating layer 11 is well during pressing and makes the tin circuit board 100 flat.

During pressing, compared to a side of the insulating layer 11 facing away from the outer wiring layer 130 facing to the inner circuit substrate 30, the s side of the outer wiring layer 130 facing away from the insulating layer 11 facing the inner circuit substrate 30 reduces the thickness of the circuit board 100 after pressing. In addition, the insulating layer 11 may also serve as a covering film for the tin circuit board 100 to protect the tin circuit board 100, so that the tin circuit board 100 does not need to be provided with a covering film, thereby further reducing the thickness of the tin circuit board 100.

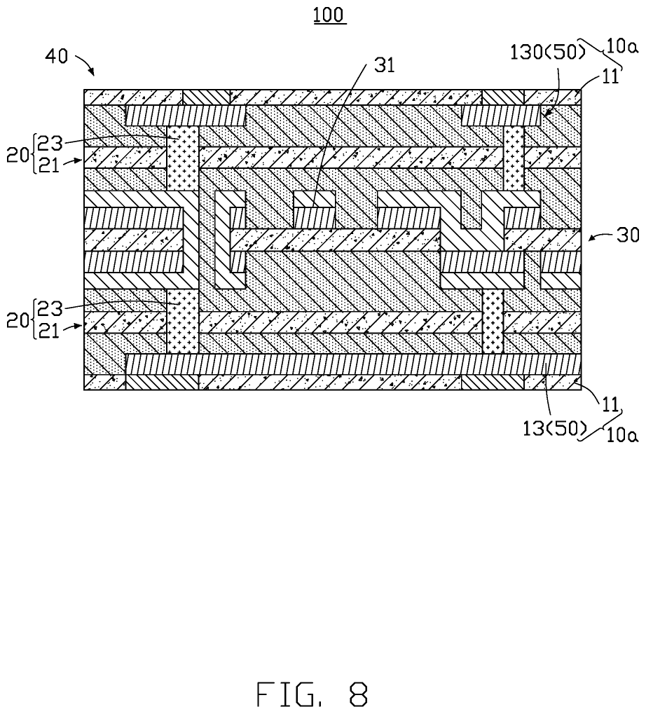

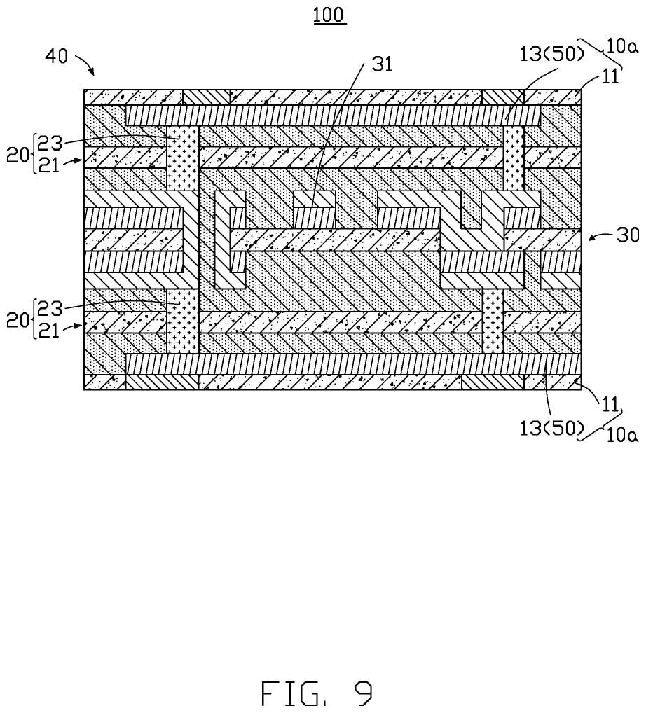

In another embodiment, the laminated board 10a may also be a single-sided copper clad laminate including the insulating layer 11 and the metal foil 13 formed on the side of the insulating layer 11. Referring to FIG. 8, one single-sided circuit substrate and one single-sided copper clad laminate are respectively pressed to opposite sides of the inner circuit substrate 30 through a bonding structure 20 to obtain a thin circuit board 100a, and a side of the metal foil 13 facing away from the insulating layer 11 faces the inner circuit substrate 30 before pressing. Referring to FIG. 9, two single-sided copper clad laminates are respectively pressed to opposite sides of the inner circuit substrate 30 through a bonding structure 20 to obtain a thin circuit board 100b, and the side of the metal foil 13 facing away from the insulating layer 11 faces the inner circuit substrate 30 before pressing.

In some embodiments, the method of manufacturing a thin circuit board 100 may further include: forming an opening 110 on the insulating layer 11 to expose the connecting pad 131 from the opening 110 to be convenient for connecting other electronic components (not shown).

In some embodiments, the method of manufacturing a thin circuit board 100 may further include: forming a solder pad 16 in the opening 110 for connecting other electronic components.

Referring to FIG. 6 to FIG. 9, an embodiment of the present disclosure of a thin circuit board 100 including a dielectric layer 40, an inner circuit substrate 30, and a metal layer 50 formed on at least one side of the inner circuit substrate 30. The inner circuit substrate 30 and the metal layer 50 are covered by the dielectric layer 40.

In some embodiments, the dielectric layer 40 includes an outermost insulating layer 11 and a bonding structure 20 sandwiched between the inner circuit substrate 30 and each metal layer 50. The metal layer 50 is covered by the bonding structure 20 and the insulating layer 11.

Specifically, in this embodiment, the two metal layers 50 are respectively formed on opposite sides of the inner circuit substrate 30, and the inner circuit substrate 30 is covered by the two bonding structures 20.

The bonding structure 20 includes an insulating substrate 21 and a conductive pillar 23 penetrating two opposite surfaces of the insulating substrate 21. Referring to FIG. 6 and FIG. 7, the insulating substrate 21 may be composed of a single-layer insulating layer or formed by stacking multiple insulating layers.

Preferably, in some embodiments, the insulating substrate 21 includes a first base 211, a second base 213, and a third base 215 stacked in that sequence. Wherein, a mechanical strength of the second base 213 is greater than a mechanical strength of the first base 211, and is greater than a mechanical strength of the third base 215, which increases a supporting force of the insulating substrate 21 to ensure a quality of drilling when drilling in the insulating substrate 21 and improve a flatness of an inner surface during drilling.

In some embodiments, the first base 211 and the third base 215 are both insulating films made of a mixture of teflon and liquid crystal polymer or a mixture of teflon and polyimide. In the mixture, a weight percentage of the liquid crystal polymer or the polyimide is 1% to 10%. A material of the first base 211 and a material of the third base 215 may be the same or different. The second base 213 may be a polyimide film.

In some embodiments, a thickness of the first base 211 and a thickness of the third base 215 may be 12.5 μm to 50 μm, respectively. In some embodiments, a dielectric constant Dₖ of the first base 211 and the third base 215 are 2.2 to 2.8, dielectric losses D_{f} are 0.001 to 0.003.

A thickness of the second base 213 is 7 μm to 50 μm. Preferably, the thickness of the second base 213 is 12.5 μm to 25 μm.

A through hole 210 penetrating two opposite surfaces of the insulating substrate 21 is formed on the insulating substrate 21. Specifically, in this embodiment, the through hole 210 sequentially penetrates the first base 211, the second base 213, and the third base 215. An aperture of the through hole 210 may be 75 μm to 200 μm. Preferably, the aperture of the through hole 210 is 100 μm to 150 μm. A ratio of a depth of the through hole 210 to the aperture is less than 3.

The pillar 23 fills the through hole 210. In this embodiment, the pillar 23 is formed by filling a hole with a conductive paste. In this embodiment, the conductive paste includes at least two of metals such as copper, tin, silver, nickel, aluminum, and molybdenum, etc. Wherein, a weight percentage of metals in the conductive paste is greater than 70%.

The pillar 23 electrically connects the metal layer 50 and the inner circuit substrate 30.

The metal layer 50 may be an outer wiring layer 130 or a metal foil 13.

The inner circuit substrate 30 includes at least one signal line 31. In some embodiments, an opening 133 is formed on the metal layer 50 corresponding to the signal line 31.

In some embodiments, an opening 110 is formed on the insulating layer 11 to expose the metal layer 50 for connecting other electronic components.

The present disclosure of the method of manufacturing the thin circuit board 100, during pressing, compared to a side of the insulating layer 11 facing away from the outer wiring layer 130 facing to the inner circuit substrate 30, the s side of the outer wiring layer 130 facing away from the insulating layer 11 facing the inner circuit substrate 30 reduces the thickness of the circuit board 100 after pressing. In addition, the insulating layer 11 may also serve as a covering film for the tin circuit board 100 to protect the tin circuit board 100, so that the tin circuit board 100 does not need to be provided with a covering film, thereby further reducing the thickness of the tin circuit board 100.

The above is only the preferred embodiment of the present disclosure, and does not limit the present disclosure in any form. Although the present disclosure has been disclosed as the preferred embodiment, it is not intended to limit the present disclosure. Any person skilled in the art, without departing from the scope of the technical solution of the present disclosure, when the technical contents disclosed above can be used to make some changes or modifications to equivalent implementations, if without departing from the technical solution content of the present disclosure, any simple modifications, equivalent changes and modifications made to the above embodiments based on the technical essence of the present disclosure still fall within the scope of the technical solution of the present disclosure.

What is claimed is:

1. A method of manufacturing a thin circuit board, comprising:
providing a laminated board, the laminated board comprising an insulating layer and a metal layer formed on a side of the insulating layer;
providing a bonding structure, the bonding structure comprising an insulating substrate and a conductive pillar penetrating two opposite surfaces of the insulating substrate;
arranging the bonding structure between the laminated board and an inner circuit substrate, a side of the metal layer facing away from the insulating layer facing the inner circuit substrate;
pressing the laminated board, the bonding structure, and the inner circuit substrate to form the thin circuit board, wherein the pillar electrically connects the metal layer and the inner circuit substrate.

2. The method of manufacturing the thin circuit board of claim 1, wherein the insulating substrate comprises a first base, a second base, and a third base stacked in that sequence, wherein a mechanical strength of the second base is greater than a mechanical strength of the first base, and is greater than a mechanical strength of the third base.

3. The method of manufacturing the thin circuit board of claim 2, wherein the first base and the third base are both insulating films made of a mixture of teflon and liquid crystal polymer or a mixture of teflon and polyimide, the second base is a polyimide film.

4. The method of manufacturing the thin circuit board of claim 3, wherein in the mixture, a weight percentage of the liquid crystal polymer or the polyimide is 1% to 10%.

5. The method of manufacturing the thin circuit board of claim 2, wherein a thickness of the first base and a thickness of the third base are 12.5 μm to 50 μm, respectively; a thickness of the second base is 7 μm to 50 μm.

6. The method of manufacturing the thin circuit board of claim 1, wherein the metal layer is a wiring layer or a metal foil.

7. The method of manufacturing the thin circuit board of claim 1, wherein the inner circuit substrate comprises a signal line, an opening is formed on the metal layer corresponding to the signal line.

8. A thin circuit board comprising:
a dielectric layer;
an inner circuit substrate; and
a metal layer formed on at least one side of the inner circuit substrate;
wherein the metal layer is covered by the dielectric layer, the dielectric layer comprises an outermost insulating layer and a bonding structure sandwiched between the inner circuit substrate and the metal layer, the metal layer is wrapped by the insulating layer and the bonding structure.

9. The thin circuit board of claim 8, wherein the insulating substrate comprises a first base, a second base, and a third base stacked in that sequence, wherein a mechanical strength of the second base is greater than a mechanical strength of the first base, and is greater than a mechanical strength of the third base.

10. The thin circuit board of claim 9, wherein the first base and the third base are both insulating films made of a mixture of teflon and liquid crystal polymer or a mixture of teflon and polyimide, the second base is a polyimide film.

11. The thin circuit board of claim 10, wherein in the mixture, a weight percentage of the liquid crystal polymer or polyimide is 1% to 10%.

12. The thin circuit board of claim 8, wherein the metal layer is a wiring layer or a metal foil.

13. The thin circuit board of claim 8, wherein the inner circuit substrate comprises a signal line, an opening is formed on the metal layer corresponding to the signal line.
